(19) United States
(12) Patent Application Publication
(10) Pub. No.: US 2016/0315196 A1
(43) Pub. Date: Oct. 27, 2016

(54) BURIED SOURCE SCHOTTKY BARRIER THIN FILM TRANSISTOR AND METHOD OF MANUFACTURE

(71) Applicant: THE GOVERNORS OF THE UNIVERSITY OF ALBERTA, Edmonton (CA)

(72) Inventors: Douglas Barlage, Edmonton (CA); Alex Ma, Edmonton (CA); Manisha Gupta, Edmonton (CA); Kyle Bothe, Edmonton (CA); Kenneth Cadien, Edmonton (CA); Amir Afshar, Edmonton (CA)

(73) Assignee: THE GOVERNORS OF THE UNIVERSITY OF ALBERTA, Edmonton, AB (CA)

(21) Appl. No.: 15/101,913

(22) PCT Filed: Dec. 4, 2014
(86) PCT No.: PCT/CA2014/000863

§ 371 Date: Jun. 5, 2016

Related U.S. Application Data
(60) Provisional application No. 61/913,601, filed on Dec. 9, 2013.
(60) Provisional application No. 61/624,174, filed on Apr. 13, 2012.

(51) Int. Cl. H01L 29/786; H01L 29/49; H01L 29/47; H01L 21/465; H01L 29/417; H01L 29/22; H01L 29/66; H01L 21/02; H01L 29/78; H01L 29/45

(52) U.S. Cl. CPC H01L 29/7869; H01L 29/78696; H01L 29/7839; H01L 29/4908; H01L 29/47; H01L 29/45; H01L 29/41766; H01L 29/41775; H01L 29/22; H01L 29/66969; H01L 21/02554; H01L 21/0262; H01L 21/465

(57) ABSTRACT

A Schottky source-gated thin film transistor is provided including: a drain contact; an insulating substrate; a source contact made of a Schottky metal; a channel connecting the buried source contact to the drain, the channel made of ZnO; and a Schottky source barrier formed between the source contact and the channel; and a gate; wherein the source contact is positioned below the channel.

### RELATED APPLICATION

This application claims the benefit of U.S. Provisional Patent Application No. 61/911,787 filed Dec. 4, 2013, and U.S. Provisional Patent Application. No. 61/913,601 filed Dec. 9, 2013, both of which are hereby incorporated by reference.

### FIELD OF THE INVENTION

The present invention relates to transistors, and more particularly to thin film transistors.

### BACKGROUND OF INVENTION

Recently, thin film transistors (TFTs) using zinc oxide (ZnO) active channels have garnered attention for many electronic and optoelectronic applications including flat panel displays and flexible electronics. ZnO, a readily grown, wide band-gap (≈3.37 eV) oxide semiconductor, and is particularly useful for inexpensive, high performance electronic applications due to its moderately-high electron mobility, transparency in the visible wavelengths, high stability, and potential for low temperature processing. For most technologies, an enhancement-mode transistor is preferable compared to a depletion-mode transistor because the enhancement-mode transistor does not require a gate voltage to switch the device off However, in the prior art there is no clear pathway to achieving a normally-off ZnO TFT. Additionally, high deposition temperatures, extrinsic/doped ZnO films, or a high temperature annealing step are usually required to obtain a high performance ZnO TFT, thereby making them costlier, more complicated, and incompatible with flexible electronic applications (if high temperature processes are used).

Pulse-width modulation (PWM) converters dominate the market primarily due to their circuit simplicity and ability to offer a voltage gain greater than unity. More specifically, the voltage gain is provided by the boost converter topology. The most common method of dictating the switching behaviour of the boosting circuit's transistor is through an extrinsic source, usually in form of a digital microcontroller (MCU). The incompatibility between a digitally driven switch and the pursuit of circuits operational at higher frequencies lies in the latter's objective to minimize both the area employed by the circuit and its bulk costs. To further elaborate, if localized boosting is required for an unstable source, the digital approach is rendered unfeasible given the size needed for the MCU.

Atomic layer deposition (ALD) is a thin film deposition method that is capable of growing highly conformal and uniform large-area films with atomic-scale precision. Thus, it is an attractive technique for the large-scale fabrication of ZnO TFTs. In particular, high-κ gate dielectrics (e.g. hafnium oxide (HfO2) and zirconium oxide (ZrO₂)) grown by ALD at low temperatures have demonstrated low leakage currents and low interface trap densities. Therefore, when integrated with ZnO TFTs, a device performance can be improved immensely (e.g. with lower operating voltages and higher transconductance). ZnO films grown by ALD have also shown some desirable characteristics for electronics applications such as moderately high mobilities at low processing temperatures (below 200° C.), thus making them compatible with plastic and flexible substrates. However, such films also typically suffer from high carrier concentrations and high conductivities, widely accepted to be the result of native defects in the film (e.g. oxygen vacancies), thereby making them less desirable for TFT applications. In order to build TFTs with high-end electrical performances using ALD ZnO channels, high mobility and high resistivity films with limited defects are necessary.

### SUMMARY OF INVENTION

In the Schottky source-gated TFT (SGTFT), a Schottky barrier contact is used for the source electrode while an ohmic contact is used for the drain electrode. This transistor, consequently, utilizes a different operating principle from conventional TFTs fabricated with ohmic source/drain contacts. Current in the SGTFT is controlled by the carrier injection barrier at the source rather than by the conductance of the channel. Based on this operating principle, a device should be normally-off if a high quality gated Schottky barrier is used; “high quality” meaning a Schottky barrier with a large rectification ratio, which is attained at the source to restrict current flow at negative gate biases. The source Schottky barrier makes the device performance less dependent on the material properties of the semiconductor used for the active channel. The SGTFT is effective using ZnO active channels, grown by pulsed laser deposition (PLD) and sol-gel (with relatively poor electrical properties). In those devices, when conventional ohmic source/drain contacts were used, there was no transistor action. Thus, the SGTFT architecture is well suited for realizing an enhancement-mode, high performance TFT that exploits the properties of ALD grown ZnO. The transistor according to the invention may include a top-gate ZnO SGTFT using a buried Schottky source barrier contact with a ZnO active channel film and insulating dielectric, both deposited via atomic layer deposition.

A ZnO source-gated TFT is provided. The device includes a buried source Schottky barrier electrode with a top gate and drain ohmic electrode. ZnO thin films deposited at 130° C. using thermal ALD are used for the device's active channel. Moreover, a thin (≈10 nm) HfO2 high-κ insulator layer grown at 100° C. by ALD is used as the gate oxide. Using this low temperature process along with the SGTFT architecture, the device ZnO SGTFT displays enhancement-mode operation with a threshold voltage of 1.1 V, a Ion/Ioff ratio of 107, a field effect mobility of 0.7 cm2 V-1 s-1, and a subthreshold swing of 192 mV/decade at low operating voltages.

A Schottky source-gated thin film transistor is provided including: a drain contact; an insulating substrate; a source contact made of a Schottky metal; a channel connecting the buried source contact to the drain, the channel made of ZnO; and a Schottky source barrier formed between the source contact and the channel; and a gate; wherein the source contact is positioned below the channel.

The saturation of the transistor may occur when the barrier induces full depletion around the channel. The drain contact may be positioned in line with the channel. The gate may be positioned above the channel, and is separated from the channel by a gate oxide. The source contact may be made of a metal that forms a Schottky barrier with the channel, such as TiW. The gate oxide may be made of HfO₂ or ZrO₂. The gate and the drain contact may be made of an AL/Au stack.

A Schottky source-gated thin film transistor is provided including a drain contact; an insulating substrate; a source contact made of a Schottky metal; a channel connecting the buried source contact to the drain, the channel made of a semiconducting material; and a Schottky source barrier formed between the source contact and the channel; and a gate; wherein the source contact is positioned below the channel.

A method of manufacture of a Schottky source-gated thin film transistor is provided, including the steps of: providing an insulating substrate; using lift-off patterning to form a Schottky metal source contact on the substrate; using a thin film deposition system to provide a layer of semiconducting material over the source contact; etching the semiconducting material; depositing a gate dielectric layer above the semiconducting material; patterning the gate dielectric material using a lift-off process; depositing a cap oxide layer on a portion of the semiconducting material; and depositing gate and drain electrodes made of an ohmic metal.

The Schottky metal may be TiW between 5 nm and 20 nm thick. The thin film deposition system may be an atomic layer deposition system using a recipe at less than 200° C. The semiconducting material may be ZnO. The etching may be done using ferric chloride.

A Schottky source-gated thin film transistor is provided, prepared by a process including the steps of: providing an insulating substrate; using lift-off patterning to form a Schottky metal source contact on the substrate; using a thin film deposition system to provide a layer of semiconducting material over the source contact; depositing a patterned semiconductor using a lift-off process; depositing a gate dielectric layer above the semiconducting material; patterning the gate dielectric material using a lift-off process; depositing a cap oxide layer on a portion of the semiconducting material; and depositing gate and drain electrodes made of an ohmic metal.

### BRIEF DESCRIPTION OF THE DRAWINGS

FIG. 1 is a cross-sectional view of an embodiment of a top-gated ZnO TFT with a buried Schottky source barrier according to the invention.

FIG. 2a is a confocal microscope image of an embodiment of a top-gated TFT with a buried Schottky source barrier according to the invention.

FIG. 2b is a graph showing output characteristics of an embodiment of a ZnO SGTFT according to the invention.

FIG. 3 is a graph showing the transfer characteristics of an embodiment of a ZnO SGTFT according to the invention at a drain voltage of 10 V.

### DETAILED DESCRIPTION OF THE INVENTION

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

The term “invention” and the like mean “the one or more inventions disclosed in this application”, unless expressly specified otherwise.

The terms “an aspect”, “an embodiment”, “embodiment”, “embodiments”, “the embodiment”, “the embodiments”, “one or more embodiments”, “some embodiments”, “certain embodiments”, “one embodiment”, “another embodiment” and the like mean “one or more (but not all) embodiments of the disclosed invention(s)”, unless expressly specified otherwise.

The term “variation” of an invention means an embodiment of the invention, unless expressly specified otherwise.

A reference to “another embodiment” or “another aspect” in describing an embodiment does not imply that the referenced embodiment is mutually exclusive with another embodiment (e.g., an embodiment described before the referenced embodiment), unless expressly specified otherwise.

The terms “including”, “comprising” and variations thereof mean “including but not limited to”, unless expressly specified otherwise.

The terms “a”, “an” and “the” mean “one or more”, unless expressly specified otherwise.

The term “plurality” means “two or more”, unless expressly specified otherwise. The term “herein” means “in the present application, including anything which may be incorporated by reference”, unless expressly specified otherwise.

The term “e.g.” and like terms mean “for example”, and thus does not limit the term or phrase it explains.

The term “respective” and like terms mean “taken individually”. Thus if two or more things have “respective” characteristics, then each such thing has its own characteristic, and these characteristics can be different from each other but need not be. For example, the phrase “each of two machines has a respective function” means that the first such machine has a function and the second such machine has a function as well. The function of the first machine may or may not be the same as the function of the second machine.

Where two or more terms or phrases are synonymous (e.g., because of an explicit statement that the terms or phrases are synonymous), instances of one such term/phrase does not mean instances of another such term/phrase must have a different meaning. For example, where a statement renders the meaning of “including” to be synonymous with “including but not limited to”, the mere usage of the phrase “including but not limited to” does not mean that the term “including” means something other than “including but not limited to”.

Neither the Title (set forth at the beginning of the first page of the present application) nor the Abstract (set forth at the end of the present application) is to be taken as limiting in any way as the scope of the disclosed invention(s). An Abstract has been included in this application merely because an Abstract of not more than 150 words is required under 37 C.F.R. Section 1.72(b) or similar law in other jurisdictions. The title of the present application and headings of sections provided in the present application are for convenience only, and are not to be taken as limiting the disclosure in any way.

Numerous embodiments are described in the present application, and are presented for illustrative purposes only. The described embodiments are not, and are not intended to be, limiting in any sense. The presently disclosed invention(s) are widely applicable to numerous embodiments, as is readily apparent from the disclosure. One of ordinary skill in the art will recognize that the disclosed invention(s) may be practiced with various modifications and alterations, such as structural and logical modifications. Although particular features of the disclosed invention(s) may be described with reference to one or more particular embodiments and/or drawings, it should be understood that such features are not limited to usage in the one or more particular embodiments or drawings with reference to which they are described, unless expressly specified otherwise.

No embodiment of method steps or product elements described in the present application constitutes the invention claimed herein, or is essential to the invention claimed herein, or is coextensive with the invention claimed herein, except where it is either expressly stated to be so in this specification or expressly recited in a claim.

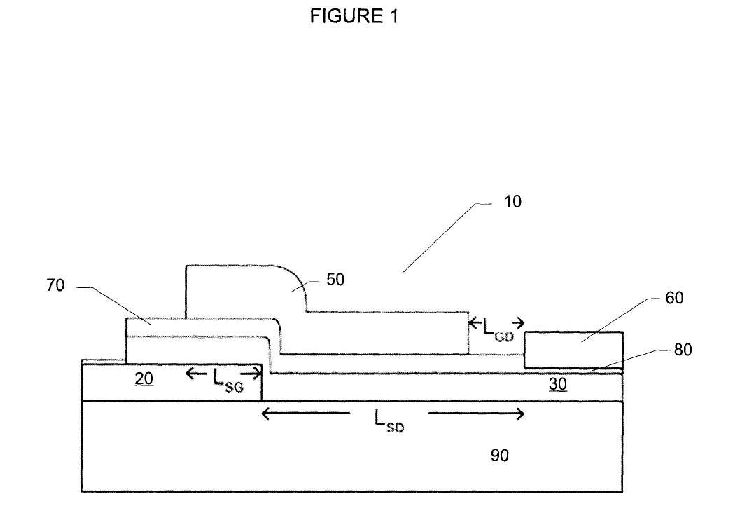

The top-gate SGTFT 10 (also referred to as “device”) according to the invention, as shown in FIG. 1, includes a buried Schottky source barrier contact 20 which functions as an electrode. Unlike conventional TFTs fabricated using ohmic source/drain contacts, the depletion region from the Schottky junction at the source is responsible for controlling the current flow in the device rather than the channel conductance. For instance, in the conventional TFT, saturation occurs when the drain region is depleted of carriers; whereas in the SGTFT, saturation occurs when the semiconductor at the source is fully depleted from the Schottky barrier. As in the conventional ZnO TFT though, the SGTFT operates as a single carrier/unipolar n-channel transistor due to the intrinsic n-type behaviour of ZnO, which is unintentionally present in all types of deposition techniques.

Advantages of the SGTFT include a lower saturation voltage, higher output impedance, faster operating speeds (due to reduced minority carrier storage), and a reduction in short-channel effects. Conversely, the drive current of device 10 is noticeably reduced compared to a conventional TFT due to the impedance of the Schottky barrier. Buried source contact 20 is used to ensure that the interface between the Schottky metal and active channel 30 layer is protected from contaminants during other processing steps, making it easier to control the variables during the Schottky junction formation.

To relax the alignment constraints of the photolithography processes, gate 50 may have a top drain contact 60 rather than a buried contact under the active channel 30 layer like source contact 20; this allows gate 50 and drain contact 60 to be fabricated at the same time. As a result, no alignment between the distance from drain contact 60 and gate 50 is predefined therefore ensuring more consistent breakdown voltages between devices. This top gate design also allows for easy integration with traditional circuits. Another aspect of device 10 is the extremely thin, for example less than 5 nm, high-κ gate oxide 70, which is possible using the ALD technique. This leads to enormous, for example, greater than 1MV/cm electric fields in channel 30 consequently increasing device performance and reducing operating voltages. A ZnO SGTFT 10 with characteristics such as high drive currents and low operating voltages can be fabricated at low processing temperatures (less than 150° C.).

In the fabrication of the ZnO SGTFT 10, due to the low processing temperatures, the device can be patterned using photolithography and lift-off processes. Devices 10 can be built on a clean, highly doped (≈1016 cm3) p-type silicon (Si) wafer covered with 50 nm thick thermal silicon oxide (SiO₂). The SGTFT architecture is applicable with nearly any kind of insulating substrate 90, which includes flexible or plastic materials if low temperature deposition processes such as those disclosed herein are used. Using this process, titanium tungsten (TiW) (12 nm thick) is first sputtered and patterned using a lift-off process to form the source Schottky metal source contact 20. TiW is a stable alloy that is resistant to acid etches and oxidation. Other materials, such as Platinum, Gold, Copper, Ruthenium, Silver, or Tungsten, that can form a Schottky barrier with ZnO are also compatible with the device architecture as the source contact electrode 20.

After forming source contact 20, ZnO may be blanket deposited by the ALD method (for example, using a Kurt J. Lesker Company ALD-150LX system) using a thermal or plasma enhanced ALD process at 130° C. The precursors used for the ZnO deposition may be diethylzinc (DEZ) and water. ZnO films are grown with a thickness of approximately 15 nm, or in the range of 5 to 50 nm, which can be monitored in-situ utilizing a J. A. Woollam Co. Inc. M-2000DI spectroscopic ellipsometer. The ZnO growth for device 10 is not limited to the ALD method; any thin film deposition technique for ZnO such as sol-gel, pulsed laser deposition (PLD), and radio frequency (rf) sputtering can also be used (a low temperature growth should be used for compatibility with flexible substrates). If the thickness of the source metal is kept below 15 nm, conformal thin film deposition techniques such as PLD can be used for the ZnO growth. Likewise, the device may include other materials, as any semiconducting material that can be deposited as a thin film at thicknesses less than 25 nm is suitable for use as active channel 30 (providing an appropriate Schottky metal is used for source contact 20).

Following the ZnO deposition, the ZnO may be etched using ferric chloride (FeCl3) to pattern channel 30 and form electrical isolation between devices 10 as needed. Other wet or dry etch processes for ZnO can be substituted for the FeCl₃. The dimensions of the channel width (W) and length (L_{SD}), the source-to-gate overlap (L_{SG}) and gate-to-drain distance (L_{GD}) of the devices 10 may be varied. Increasing L_{SG} leads to higher output current due to increased lowering of the effective source barrier while L_{GD} affects the device breakdown voltage. In an experiment, hafnium dioxide (HfO₂) was blanket deposited by plasma-enhanced ALD at 100° C. following a brief remote oxygen plasma (ROP) clean for use as the high-k gate insulator layer. Both the channel and gate dielectric films are compatible with inexpensive plastic or polymer-based substrates due to the low growth temperatures of the process.

The HfO₂ deposition may be done using tetrakis(dimethylamino)hafnium (TDMAHf) as a precursor with ROP. Additionally, as a result of the low growth temperature, the gate oxide can be patterned using a lift-off process. In an experiment, a 10 cycle (≈1.7 nm thick) HfO₂ cap oxide layer 80 was first deposited after etching the ZnO (and before photolithography) to protect the thin ZnO film from the photoresist developer, which was seen to etch ZnO. The only noticeable negative effect of using the HfO₂ cap oxide layer 80 is increasing the contact resistance; neglecting the cap oxide layer is not detrimental to the device performance.

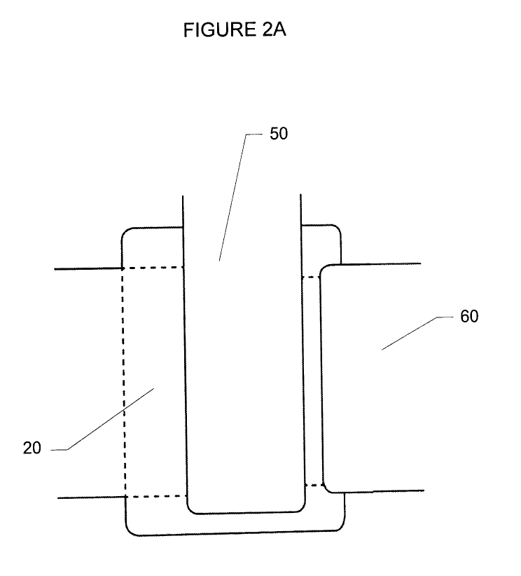

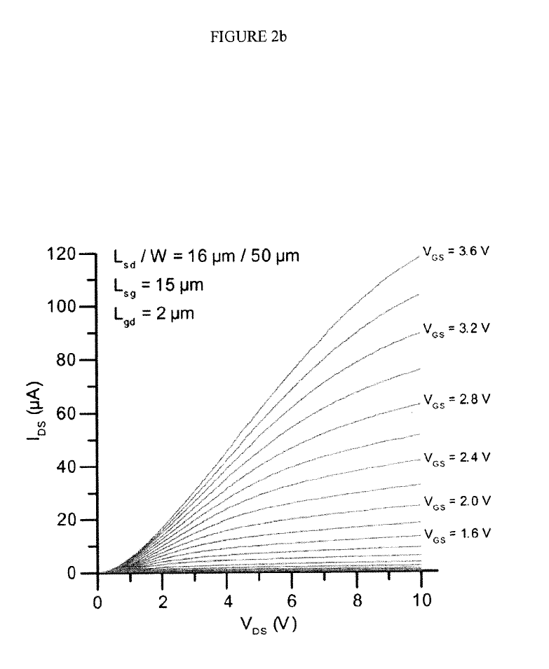

Following the photolithography for the gate oxide patterns, more cycles, for example another 50 cycles, of HfO₂ are deposited. In the experiment this led to an approximately 10 nm, or within a range of 3 to 20 nm, thick HfO₂ film for the gate oxide 70 dielectric layer (including HfO₂ cap oxide layer 80) as measured from ellipsometry. Besides HfO2, any other insulating material (e.g. ZrO₂ or spin-on-dielectrics) that can be deposited as a thin film is suitable for use as the gate oxide 70 (the gate dielectric layer) in device 10. Lastly, an ohmic metal is deposited and patterned with lift-off to form top gate 50 and drain contact 60 electrodes. An Aluminum/gold (Al/Au) stack (of a large range, including 20 nm/60 nm) can be used without any post-deposition annealing as the ohmic contacts. Alternatively, different metals can be used so long as they secure to ZnO and HfO₂. A schematic of device 10 is shown in FIG. 1, and a confocal microscope image of a typical device is shown in the inset in FIG. 2a. In FIG. 2b, as shown in the graph, V_{GS} is at 3.6 V for the top curve and decreases in −0.2 V increments until pinch-off. Using Hall Effect measurements, the electron concentration of the ALD ZnO is on the order of 1017 cm⁻³. The measurements of L_{SD}/W, L_{SG}, and L_{GD} indicated in FIG. 2b are typical, but are scalable downwards by a factor of 100 and upwards by a factor of 10.

The output characteristics (drain current (I_{DS}) vs. drain voltage (V_{DS})) of a typical ZnO SGTFT 10 with a buried TiW source Schottky contact 20 (measured using the Keithley Instruments Inc. 4200 semiconductor characterization system) is shown in FIG. 2b. The dimensions of the device 10 are also given in the figure. Similar to other ZnO TFTs that utilized high-κ k dielectrics, there is high transconductance over a low operating voltage range. Also, n-channel behaviour is present as current density increased as V_{GS} was increased. The device 10 in FIG. 2b also showed good drive current, reaching 120 μA at a gate voltage (VGS) of 3.6 V, despite the low temperature of the ALD ZnO growth.

The saturation voltages in device 10 are much lower than prior devices that did not use the source Schottky barrier; however, they can be made even lower with a higher quality Schottky junction. From current-voltage (IV) measurements of Schottky diodes formed from TiW contacts on the ALD ZnO, an experiment measured a current on/off ratio of 10 and an ideality factor of greater than 2 using thermionic emission theory. These results are characteristic of a highly non-ideal Schottky barrier and are poor compared to other-known Schottky metals on ZnO. Regardless of poorer Schottky barrier properties though, using TiW as the source barrier metal is attractive due to its relatively low cost and robustness. In the saturation regime, there is high series resistance being exhibited as seen by the noticeable positive slope in the family of curves. This is most likely the result of the high carrier concentration in the channel along with the non-ideal source Schottky barrier.

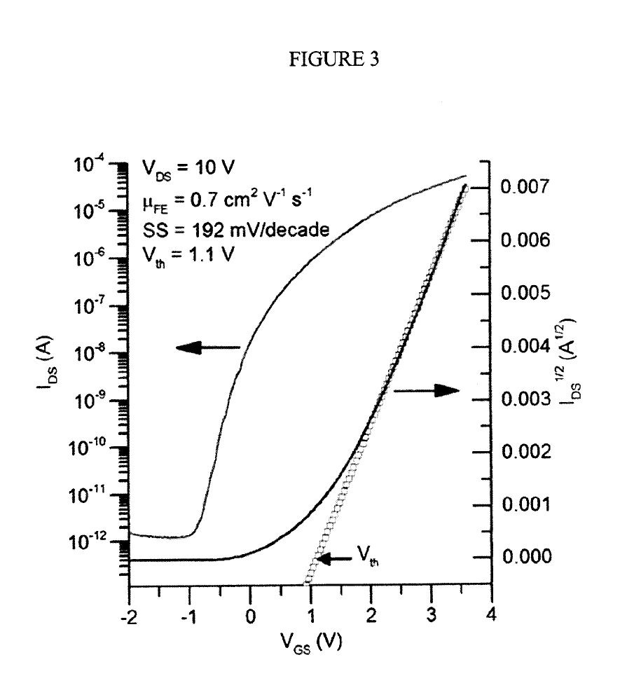

The transfer characteristics (I_{DS} vs. V_{GS}) of the ZnO SGTFT at a drain voltage of 10 V are shown in FIG. 3. The method of extracting the threshold voltage (V_{TH}) from the linear portion of (I_{DS})1/2 vs. V_{GS} is also shown. From fitting a straight line to the square root of I_{DS} versus V_{GS} (also shown in FIG. 3), the threshold voltage (V_{TH}) was extracted to be 1.1 V. The maximum current on/off ratio (I_{ON}/I_{OFF}) reaches 107, and the off-current reaches low values of approximately 1×10-12 A at a pinch-off voltage of −1 V. Although the pinch-off voltage is negative, device 10 can nonetheless operate as an enhancement-mode transistor due to the positive V_{TH} and the relatively low current at zero gate bias (≈1.5×10-8 A) compared to the on-current values (greater than 1×10-5 A).

Carriers in SGTFT 10 are controlled by the gated field at the source, so the turn-on conditions for SGTFT 10 are less dependent on the properties of active channel 30. Particularly, process variables such as the thickness and carrier concentration of channel 30 have a lesser effect on Vth compared to the conventional TFT. This also implies that the Vth of the SGTFT is mostly determined by the properties of the source Schottky barrier (e.g. barrier height), which is advantageous for improving the fault tolerance of fabricating enhancement-mode devices. From fitting the linear portion of the transfer curve, the field-effect mobility (μFE) of the transistor was extracted to be 0.7 cm2 V-1 s-1 using Eq. (1) (which applies when device 10 is in the saturation region):

$${I}_{DS} = [ \frac{W {μ}_{FE} {C}_{ox}}{2 {L}_{SD}} ] {( {V}_{GS} - {V}_{th} )}^{2} , ( {V}_{DS} \geq {V}_{DS , sat} ) \qquad ( 1 )$$

where Cₒₓ is the gate oxide capacitance per unit area. The extracted channel mobility is within the same order of magnitude as other reported ALD ZnO TFTs that used low temperature processes. Therefore, the electrical performance of the SGTFT is comparable with other ALD ZnO TFTs that used conventional TFT architectures. The subthreshold swing (SS), which is defined by Eq. (2), was extracted to be 192 mV/decade at the maximum slope in the transfer curve:

$$SS = \frac{\partial {V}_{GS}}{\partial {log}_{10} ( {I}_{DS} )} \qquad ( 2 )$$

Compared to most ZnO TFTs, the SS of device 10 is among the lowest. This is due to the 10 nm thick high-κ k gate oxide, which is the thinnest gate oxide reported for ZnO TFTs. The thin gate oxide helps reduce fabrication costs, due to a shorter deposition time, while also allowing for higher electric fields in channel 30 leading to higher transconductance and better charge control. Measurements of the gate leakage current did not show any breakdown phenomena until V_{GS} surpassed 5 V. When breakdown did occur, the characteristics of the leakage current resembled that of Fowler-Nordheim tunneling. Consequently, these measurements indicate that the ALD-grown HfO₂ is high quality gate oxide. Based on the above results, despite the relatively high carrier concentration of the ZnO channel deposited by ALD at 130° C., experiments were able to fabricate a ZnO transistor with good electrical characteristics that is suitable for flexible electronics applications by using a distinctive buried source Schottky barrier and top gate SGTFT structure.

The above-described embodiments have been provided as examples, for clarity in understanding the invention. A person with skill in the art will recognize that alterations, modifications and variations may be effected to the embodiments described above while remaining within the scope of the invention as defined by claims appended hereto.

What is claimed is:

1. A Schottky source-gated thin film transistor comprising:
a. a drain contact;
b. an insulating substrate;
c. a source contact made of a Schottky metal;
d. a channel connecting the buried source contact to the drain, the channel made of ZnO; and a Schottky source barrier formed between the source contact and the channel; and
e. a gate;
wherein the source contact is positioned below the channel.

2. The Schottky source-gated thin film transistor of claim 1, wherein saturation of the transistor occurs when the barrier induces full depletion around the channel.

3. The Schottky source-gated thin film transistor of claim 1 wherein the drain contact is positioned in line with the channel.

4. The Schottky source-gated thin film transistor of claim 1 wherein the gate is positioned above the channel, and is separated from the channel by a gate oxide.

5. The Schottky source-gated thin film transistor of claim 1 wherein the source contact is made of a metal that forms a Schottky barrier with the channel.

6. The Schottky source-gated thin film transistor of claim 5 wherein the source contact is made of TiW.

7. The Schottky source-gated thin film transistor of claim 4 wherein the gate oxide is made of HfO₂.

8. The Schottky source-gated thin film transistor of claim 4 wherein the gate oxide is made of ZrO₂.

9. The Schottky source-gated thin film transistor of claim 1 wherein the gate is made of an AL/Au stack.

10. The Schottky source-gated thin film transistor of claim 1 wherein the drain contact is made of an Au/Al stack.

11. A Schottky source-gated thin film transistor comprising:
a. a drain contact;
b. an insulating substrate;
c. a source contact made of a Schottky metal;
d. a channel connecting the buried source contact to the drain, the channel made of a semiconducting material; and a Schottky source barrier formed between the source contact and the channel; and
e. a gate;
wherein the source contact is positioned below the channel.

12. A method of manufacture of a Schottky source-gated thin film transistor, comprising the steps of:
a. providing an insulating substrate;
b. using lift-off patterning to form a Schottky metal source contact on the substrate;
c. using a thin film deposition system to provide a layer of semiconducting material over the source contact;
d. etching the semiconducting material;
e. depositing a gate dielectric layer above the semiconducting material;
f. patterning the gate dielectric material using a lift-off process;
g. depositing a cap oxide layer on a portion of the semiconducting material; and
h. depositing gate and drain electrodes made of an ohmic metal.

13. The method of claim 12 wherein the Schottky metal is TiW and is between 5 nm and 20 nm thick.

14. The method of claim 12 wherein the thin film deposition system is an atomic layer deposition system using a recipe at less than 200° C.

15. The method of claim 12 wherein the semiconducting material is ZnO.

16. The method of claim 12 wherein the etching is done using ferric chloride.

17. A Schottky source-gated thin film transistor prepared by a process comprising the steps of:
a. providing an insulating substrate;
b. using lift-off patterning to form a Schottky metal source contact on the substrate;
c. using a thin film deposition system to provide a layer of semiconducting material over the source contact;
d. depositing a patterned semiconductor using a lift-off process;
e. depositing a gate dielectric layer above the semiconducting material;
f. patterning the gate dielectric material using a lift-off process;
g. depositing a cap oxide layer on a portion of the semiconducting material; and
h. depositing gate and drain electrodes made of an ohmic metal.
